(19) United States
(12) Patent Application Publication
(10) Pub. No.: US 2026/0173806 A1
(43) Pub. Date: Jun. 18, 2026

(54) WAFER FIXED CHARGE CONTROL IN PHYSICAL VAPOR DEPOSITION

(71) Applicant: Applied Materials, Inc., Santa Clara, CA (US)

(72) Inventors: Lei Zhang, Wuhan, Hubei (CN); Xi Wu, Shenzhen (CN); Ruida An, Shenzhen, Guangdong Province (CN); Ling Li, Guangzhou, Guangdong (CN); Dawei Cai, Guangzhou, Guangdong (CN); Zhen Chen, Wuhan City (CN); Chongchong Xia, Wuhan, Hubei Province (CN); Wuxiang Li, Shenzhen, Guangdong (CN); Haibo Zhou, Wuhan City, Hubei Province (CN)

(73) Assignee: Applied Materials, Inc., Santa Clara, CA (US)

(21) Appl. No.: 19/105,557

(22) PCT Filed: Dec. 18, 2024
(86) PCT No.: PCT/CN2024/140187

§ 371 Date: Feb. 21, 2025

(51) Int. Cl. H01L 21/683; H01J 37/32; H01L 21/02; H10F 39/00

(52) U.S. Cl. CPC H10P 72/722; H01J 37/32715; H10F 39/014; H01J 2237/332; H10P 14/6329; H10P 14/69393; H10P 14/69394

(57) ABSTRACT

Methods and apparatus for reducing fixed charge in a dielectric layer during deposition are described. A dielectric layer is deposited on a substrate chucked to a support surface of an electrostatic chuck and the current passing through the center tap of the electrostatic chuck is measured. A variable resistor of the center tap is adjusted to control the current flowing through the substrate. Methods for chamber matching using the fixed charge are also described,

### TECHNICAL FIELD

Embodiments of the disclosure generally relate to physical vapor deposition (PVD) process chambers and methods of forming electronic devices. In particular, embodiments of the disclosure relate to semiconductor manufacturing processing chambers comprising a variable resistor to tune wafer charging during deposition. Embodiments of the disclosure also relate to methods of controlling the wafer level fixed charge.

### BACKGROUND

The semiconductor processing industry continues to strive for larger production yields while increasing the uniformity of layers deposited on substrates having larger surface areas. These same factors in combination with new materials also provide higher Integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

The semiconductor Industry faces many challenges in the pursuit of device miniaturization which involves rapid scaling of nanoscale features. Such issues include the introduction of complex fabrication steps such as multiple lithography steps and integration of high-performance materials.

During formation of some coatings (e.g., tantalum oxide), the impedance of the process chamber increases, resulting in an increase in current through the electrostatic chuck (ESC) center tap. The increased current flow can Impact the film electrical properties, such as the flat-band voltage (Vfb) and Interface trapped charge (Dit).

Therefore, there is an ongoing need for Improved processing chambers and deposition methods.

### SUMMARY

Embodiments of the present disclosure are directed to methods of controlling fixed charge in a dielectric layer. A substrate is chucked to a support surface of an electrostatic chuck positioned within a processing chamber. The electrostatic chuck has a first electrode in a first portion, a second electrode in a second portion and a center tap positioned between the first electrode and the second electrode. The center tap is in electrical communication with electrical ground through a variable resistor. The dielectric layer is deposited on the substrate using a plasma in the processing chamber. The current through the substrate is measured during deposition using the center tap of the electrostatic chuck. The variable resistor of the center tap is adjusted to control the current flowing through the substrate.

Additional embodiments of the disclosure are directed to methods of tuning a processing chamber. Current flowing through a substrate on an electrostatic chuck is measured during deposition of a dielectric layer using a plasma in the processing chamber. The current is measured through a center tap of the electrostatic chuck. A variable resistor connected to the center tap is adjusted to control the current flowing through the substrate to match a reference current from a reference processing chamber.

Further embodiments of the disclosure are directed to electrostatic chucks comprising a support body having a support surface with a first electrode, a second electrode and a center tap. The first electrode is in a first portion of the support body and is connected to a power source through a first transmission line. The second electrode is in a second portion of the support body and is connected to the power source through a second transmission line. The center tap is between the first electrode and the second electrode and is connected to the power source through a variable resistor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are Illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 Illustrates a schematic representation of a PVD chamber in accordance with one or more embodiments of the disclosure;

FIG. 2 illustrates an energy level diagram for a typical metal-oxide-semiconductor (MOS) system;

FIG. 3 illustrates a partial schematic diagram of a four transistor back-side Illumination complementary metal-oxide-semiconductor (BSI CIS) image sensor;

FIG. 4 shows a partial view of a physical vapor deposition process chamber according to one or more embodiment of the disclosure;

FIG. 5 Illustrates a schematic representation of a process chamber including an electrostatic chuck within the substrate support pedestal in accordance with one or more embodiment of the disclosure;

FIG. 6 shows a flowchart of a method of controlling fixed charge in a dielectric layer according to one or more embodiments of the disclosure;

FIG. 7 Illustrates a schematic representation of the electrical pathway of method according to one or more embodiments of the disclosure; and

FIG. 8 Illustrates a flowchart for a method for chamber matching or tuning of a process chamber according to one or more embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” or “wafer” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface,

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of ±15% or less, of the numerical value. For example, a value differing by ±14%, ±10%, ±15%, ±2%, ±11%, ±0.5%, or ±0,1% would satisfy the definition of “about.”

Spatially relative terms, such as “beneath,” “below,” “lower,” “above,” “upper” and the like, may be used herein for ease of description to describe one element or feature's relationship to another element(s) or feature(s) as Illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is Incorporated into the specification as if it were Individually recited herein. All methods described herein can be performed in any suitable order unless otherwise indicated herein or otherwise clearly contradicted by context. The use of any and all examples, or exemplary language (e.g., “such as”) provided herein, is intended merely to better Illuminate the materials and methods and does not pose a limitation on the scope unless otherwise claimed. No language in the specification should be construed as indicating any non-claimed element as essential to the practice of the disclosed materials and methods,

The term “on” indicates that there is direct contact between elements. The term “directly on” indicates that there is direct contact between elements with no Intervening elements.

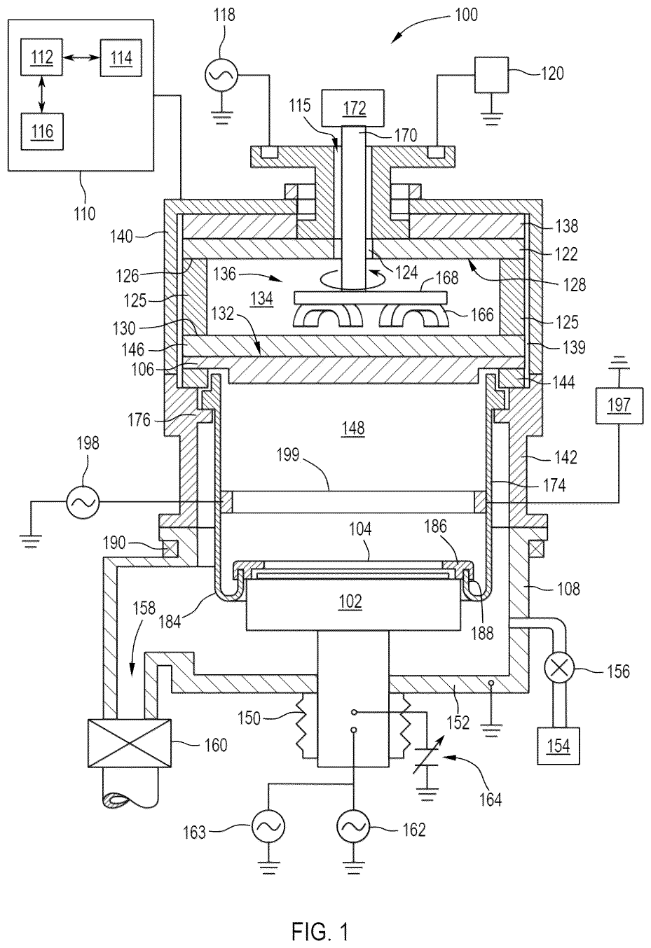

One or more embodiments of the disclosure are directed to physical vapor deposition (PVD) processes that may be performed in a physical vapor deposition (PVD) processing system. FIG. 1 illustrates a schematic representation of a PVD chamber in accordance with one or more embodiments of the disclosure. The PVD chamber illustrated in FIG. 1 includes a magnetron. However, the skilled artisan will recognize that this is merely representative of one possible configuration and should not be taken as limiting the scope of the disclosure.

The process chamber 100 depicted in FIG. 1 includes a substrate support pedestal 102 for receiving a substrate 104 thereon, and a sputtering source, such as a target 106. The substrate support pedestal 102 may be located within a grounded chamber wall 108, which may be a chamber wall (as shown) or a grounded shield such as a ground shield 140 covering at least some portions of the process chamber 100 above the target 106. In some embodiments, the ground shield 140 extends below the target to enclose the substrate support pedestal 102.

The process chamber 100 in the illustrated embodiment further comprises an RF power source 118 to provide RF energy to the target 106 including source material. In some embodiments, the process chamber includes a feed structure for coupling RF and pulsed-DC energy to the target 106. The feed structure is an apparatus for coupling RF and pulsed-DC energy to the target, or to an assembly containing the target, for example, as described herein. A first end of the feed structure can be coupled to an RF power source 118 and a pulsed-DC power source 120, which can be respectively utilized to provide RF and pulsed-DC energy to the target 106. For example, the DC power source 120 may be utilized to apply a negative voltage, or bias, to the target 106. In some embodiments, RF energy supplied by the RF power source 118 may be suitable to provide frequency as described above, or range in frequency. In some embodiments, about 0.25 to about 6 kilowatts of RF energy may be provided to the target at a frequency of from about 13 to about 60 MHz, or 27 to about 40 MHz, or about 40 MHz. In some embodiments, a plurality of RF power sources may be provided (Le,, two or more) to provide RF energy in a plurality of the above frequencies. The feed structure may be fabricated from suitable conductive materials to conduct the RF and pulsed-DC energy from the RF power source 118 and the pulsed-DC power source 120.

In some embodiments, the target 106 is configured as is known in the art and may include one or more metal containing targets or source materials as described herein. In embodiments, one or more cobalt targets and one or more cobalt coils are positioned above or adjacent to a substrate in a PVD chamber, and the one or more cobalt targets and one or more cobalt coils are configured to deposit cobalt in a layer atop a substrate as described herein.

In some embodiments, the process chamber includes an RF power source 198 configured to provide RF energy to coil 199 and/or pulsed-DC energy from DC power source 197 to the coil 199. For example, the DC power source 197 may be utilized to apply a negative voltage, or bias, to the coil 199. In some embodiments, RF energy supplied by the RF power source 198 may be suitable to provide frequency as described above, or range in frequency. In some embodiments, about 0.25 to about 6 kilowatts of RF energy may be provided to the coil at a frequency of from about 13 to about 60 MHz, or 27 to about 40 MHz, or about 40 MHz. In embodiments, about 0.5 to 15.0 kilowatts of DC power is provided to the cobalt or cobalt containing coil such as coil 199. In some embodiments, a plurality of RF power sources may be provided (i.e., two or more) to provide RF energy in a plurality of the above frequencies. In embodiments, a feed structure may be fabricated from suitable conductive materials to conduct the RF and pulsed-DC energy from the RF power source 198 and the pulsed-DC power source 197. In some embodiments, the coil 199 is configured to include one or more cobalt coil or cobalt source materials as described herein.

In addition, the PVD process chamber 100 as shown in FIG. 1 is maintained at a pressure of about 1 mTorr to about 150 mTorr, or about 10 mTorr to about 150 mTorr. About 10 W to 1000 W, for example at least about 100 W, of RF bias power may be provided to the substrate support at a frequency of about 5 to about 10 MHz, or about 10 to about 15 MHz, or about 13.56 MHz.

In embodiments, the PVD process Includes suitable gases to facilitate sputtering. A gas source may provide a suitable gas species such as an inert gas, such as argon, krypton, neon, or the like, hydrogen (H₂), or combinations thereof. In some embodiments, the plasma process includes a plasma formed from hydrogen or an inert gas. In some embodiments, only H₂ gas is provided.

Referring back to FIG. 1, a PVD chamber such as, for example, a PVD chamber (e.g., process chamber 100) suitable for use herein includes target 106 and coil 199 as described above. In some embodiments, the process chamber 100 includes a feed structure for coupling RF and pulsed-DC energy to the target 106. The feed structure is an apparatus for coupling RF and pulsed-DC energy to the target, or to an assembly containing the target, for example, as described herein. A first end of the feed structure can be coupled to an RF power source 118 and a pulsed-DC power source 120, which can be respectively utilized to provide RF and pulsed-DC energy to the target 106. For example, the DC power source 120 may be utilized to apply a negative voltage, or bias, to the target 106. In some embodiments, RF energy supplied by the RF power source 118 may be suitable to provide frequency as described above.

In some embodiments, the feed structure may have a suitable length to facilitate substantially uniform distribution of the respective RF and pulsed-DC energy about the perimeter of the feed structure. For example, in some embodiments, the feed structure may have a length of between about 1 to about 12 inches, or about 4 inches. In some embodiments, the body may have a length to Inner diameter ratio of at least about 1:1. Providing a ratio of at least 1:1 or longer provides for more uniform RF delivery from the feed structure (i.e., the RF energy is more uniformly distributed about the feed structure to approximate RF coupling to the true center point of the feed structure. The inner diameter of the feed structure may be as small as possible, for example, from about 1 inch to about 6 inches, or about 4 inches in diameter. Providing a smaller inner diameter facilitates Improving the length to ID ratio without increasing the length of the feed structure,

The second end of the feed structure may be coupled to a source distribution plate 122. The source distribution plate includes a hole 124 disposed through the source distribution plate 122 and aligned with a central opening of the feed structure. The source distribution plate 122 may be fabricated from suitable conductive materials to conduct the RF and pulsed-DC energy from the feed structure.

The source distribution plate 122 may be coupled to the target 106 via a conductive member 125. The conductive member 125 may be a tubular member having a first end 126 coupled to a target-facing surface 128 of the source distribution plate 122 proximate the peripheral edge of the source distribution plate 122. The conductive member 125 further includes a second end 130 coupled to a source distribution plate-facing surface 132 of the target 106 (or to the backing plate 146 of the target 106) proximate the peripheral edge of the target 106.

A cavity 134 may be defined by the inner-facing walls of the conductive member 125, the target-facing surface 128 of the source distribution plate 122 and the source distribution plate-facing surface 132 of the target 106. The cavity 134 is fluidly coupled to the central opening 115 of the body via the hole 124 of the source distribution plate 122. The cavity 134 and the central opening 115 of the body may be utilized to at least partially house one or more portions of a rotatable magnetron assembly 136 as Illustrated in FIG. 1 and described further below. In some embodiments, the cavity may be at least partially filled with a cooling fluid, such as water (H₂O) or the like.

A ground shield 140 may be provided to cover the outside surfaces of the lid of the process chamber 100. The ground shield 140 may be coupled to ground, for example, via the ground connection of the chamber body. The ground shield 140 has a central opening to allow the feed structure to pass through the ground shield 140 to be coupled to the source distribution plate 122. The ground shield 140 may comprise any suitable conductive material, such as aluminum, copper, or the like. An Insulative gap 139 is provided between the ground shield 140 and the outer surfaces of the source distribution plate 122, the conductive member 125, and the target 106 (and/or backing plate 146) to prevent the RF and pulsed-DC energy from being routed directly to ground. The Insulative gap may be filled with air or some other suitable dielectric material, such as a ceramic, a plastic, or the like.

In some embodiments, a ground collar may be disposed about the body and lower portion of the feed structure. The ground collar is coupled to the ground shield 140 and may be an integral part of the ground shield 140 or a separate part coupled to the ground shield to provide grounding of the feed structure. The ground collar may be made from a suitable conductive material, such as aluminum or copper. In some embodiments, a gap disposed between the Inner diameter of the ground collar and the outer diameter of the body of the feed structure may be kept to a minimum and be just enough to provide electrical Isolation. The gap can be filled with isolating material like plastic or ceramic or can be an air gap. The ground collar prevents cross-talk between an RF feed and the body, thus improving plasma, and processing, uniformity.

An isolator plate 138 may be disposed between the source distribution plate 122 and the ground shield 140 to prevent the RF and pulsed-DC energy from being routed directly to ground. The isolator plate 138 has a central opening to allow the feed structure to pass through the isolator plate 138 and be coupled to the source distribution plate 122. The isolator plate 138 may comprise a suitable dielectric material, such as a ceramic, a plastic, or the like. Alternatively, an air gap may be provided in place of the isolator plate 138. In embodiments where an air gap is provided in place of the isolator plate, the ground shield 140 may be structurally sound enough to support any components resting upon the ground shield 140.

The target 106 may be supported on a grounded conductive aluminum adapter such as 142 through a dielectric isolator 144. The target 106 comprises a material to be deposited on the substrate 104 during sputtering. In some embodiments, the backing plate 146 may be coupled to the source distribution plate-facing surface 132 of the target 106. The backing plate 146 may comprise a conductive material, such as cobalt, or the same material as the target, so RF and pulsed-DC power can be coupled to the target 106 via the backing plate 146. Alternatively, the backing plate 146 may be non-conductive and may include conductive elements (not shown) such as electrical feedthroughs or the like for coupling the source distribution plate-facing surface 132 of the target 106 to the second end 130 of the conductive member 125. The backing plate 146 may be included for example, to improve structural stability of the target 106.

The substrate support pedestal 102 has a material-receiving surface facing the principal surface of the target 106 and supports the substrate 104 to be sputter coated in planar position opposite to the principal surface of the target 106. The substrate support pedestal 102 may support the substrate 104 in a central region 148 of the process chamber 100. The central region 148 is defined as the region above the substrate support pedestal 102 during processing (for example, between the target 106 and the substrate support pedestal 102 when in a processing position).

In some embodiments, the substrate support pedestal 102 may be vertically movable through a bellows 150 connected to a bottom chamber wall 152 to allow the substrate 104 to be transferred onto the substrate support pedestal 102 through a load lock valve (not shown) in the lower portion of processing the process chamber 100 and thereafter raised to a deposition, or processing position. One or more processing gases may be supplied from a gas source 154 through a mass flow controller 156 into the lower part of the process chamber 100. An exhaust port 158 may be provided and coupled to a pump (not shown) via a valve 160 for exhausting the interior of the process chamber 100 and facilitating maintaining a desired pressure inside the process chamber 100.

In embodiments, an RF bias power source 162 may be coupled to the substrate support pedestal 102 in order to induce a negative DC bias on the substrate 104. In addition, in some embodiments, a negative DC self-bias may form on the substrate 104 during processing. For example, RF power supplied by the RF bias power source 162 may range in frequency from about 2 MHz to about 60 MHz, for example, non-limiting frequencies such as 2 MHz, 13,56 MHz, or 60 MHz can be used. Further, a second RF bias power source 163 may be coupled to the substrate support pedestal 102 and provide any of the frequencies discussed above for use with the RF bias power source 162. In other applications, the substrate support pedestal 102 may be grounded or left electrically floating. For example, a capacitance tuner 164 may be coupled to the substrate support pedestal for adjusting voltage on the substrate 104 for applications where RF bias power may not be desired.

In some embodiments, the PVD processing chamber includes one or more coils 199 as shown in FIG. 1. In embodiments, the one or more coils 199 comprise pure or substantially pure cobalt. In embodiments, the PVD processing chamber is configured to supply RF to the one or more coils 199. In embodiments, RF may be applied to the one or more coil 199 in an amount sufficient to provide a cobalt layer atop the substrate and within the features of the substrate. In embodiments, the PVD chamber has dual material sources (a target and a coil) (first and second sources) configured to provide cobalt to the substrate as described herein. In some embodiments, coil 199 is an inductive coil may be positioned nearer to the substrate support than the target. The coil 199 may be formed from a material similar or equal in composition to the target, such as for example, cobalt, to act as a secondary sputtering target. In embodiments, a power source applies current to the coil to Induce an RF field within the process chamber and couple power to the plasma to increase plasma density, i.e. concentration of reactive ions.

In embodiments, an RF bias power source 198 may be coupled to the coil 199 in order to Induce a negative DC bias on the coil 199. In addition, in some embodiments, a negative DC self-bias may form on the coil 199 during processing. For example, RF power supplied by the RF bias power source 198 may range in frequency from about 2 MHz to about 60 MHz, for example, non-limiting frequencies such as 2 MHz, 13.56 MHz, or 60 MHz can be used.

In some embodiments, a rotatable magnetron assembly 136 may be positioned proximate a back surface (e.g., source distribution plate-facing surface 132) of the target 106. The rotatable magnetron assembly 136 includes a plurality of magnets 166 supported by a base plate 168. The base plate 168 connects to a rotation shaft 170 coincident with the central axis of the process chamber 100 and the substrate 104. A motor 172 can be coupled to the upper end of the rotation shaft 170 to drive rotation of the magnetron assembly 136. The magnets 166 produce a magnetic field within the process chamber 100, generally parallel and close to the surface of the target 106 to trap electrons and increase the local plasma density, which in turn increases the sputtering rate. The magnets 166 produce an electromagnetic field around the top of the process chamber 100, and magnets 166 are rotated to rotate the electromagnetic field which influences the plasma density of the process to more uniformly sputter the target 106. For example, the rotation shaft 170 may make about 0 to about 150 rotations per minute.

In some embodiments, the process chamber 100 may further include a process kit shield 174 connected to a ledge 176 of the adapter 142. The adapter 142 in turn is sealed and grounded to the aluminum chamber sidewall such as chamber wall 108. Generally, the process kit shield 174 extends downwardly along the walls of the adapter 142 and the chamber wall 108 downwardly to below an upper surface of the substrate support pedestal 102 and returns upwardly until reaching an upper surface of the substrate support pedestal 102 (e.g., forming a u-shaped portion 184 at the bottom). Alternatively, the bottom portion of the process kit shield may have any suitable shape. A cover ring 186 rests on the top of an upwardly extending lip 188 of the process kit shield 174 when the substrate support pedestal 102 is in a lower, loading position but rests on the outer periphery of the substrate support pedestal 102 when the substrate support pedestal 102 is in an upper, deposition position to protect the substrate support pedestal 102 from sputter deposition. An additional deposition ring (not shown) may be used to shield the periphery of the substrate 104 from deposition. Embodiments of a process kit shield are discussed below in accordance with the present disclosure,

In some embodiments, a magnet 190 may be disposed about the process chamber 100 for selectively providing a magnetic field between the substrate support pedestal 102 and the target 106. For example, as shown in FIG. 1, the magnet 190 may be disposed about the outside of the chamber wall 108 in a region just above the substrate support pedestal 102 when in processing position. In some embodiments, the magnet 190 may be disposed additionally or alternatively in other locations, such as adjacent the adapter 142. The magnet 190 may be an electromagnet and may be coupled to a power source (not shown) for controlling the magnitude of the magnetic field generated by the electromagnet.

A controller 110 may be provided and coupled to various components of the process chamber 100 to control the operation thereof. The controller 110 includes a central processing unit (CPU) 112, a memory 114, and support circuits 116. The controller 110 may control the process chamber 100 directly, or via computers (or controllers) associated with particular process chamber and/or support system components. The controller 110 may be one of any form of general-purpose computer processor configured for use in an industrial setting for controlling various chambers and sub-processors. The memory 114, or computer readable medium of the controller 110 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 116 are coupled to the CPU 112 for supporting the processor in a conventional manner. The support circuits 116 include cache, power supplies, clock circuits, input/output circuitry and subsystems, and the like. Inventive methods as described herein may be stored in the memory 114 as software routine executed or invoked to control the operation of the process chamber 100 in the manner described herein. The software routine may also be stored and/or executed by a second CPU (not shown) remotely located from the hardware being controlled by the CPU 112.

During physical vapor deposition, insulating material is deposited on the process kit shield 174 causing changes in the process chamber impedance. For example, during deposition of tantalum oxide (Taoₓ), tantalum oxide is deposited on the substrate surface as well as the process kit shield 174. The coating of insulating material on the process kit shield 174 causes the chamber impedance to increase, which results in more electrical current channeled through the center tap of the electrostatic chuck. The current flow can impact film electrical properties, such as, the Interface trapped charge (Dit) and the flat-band voltage (V_{fb}).

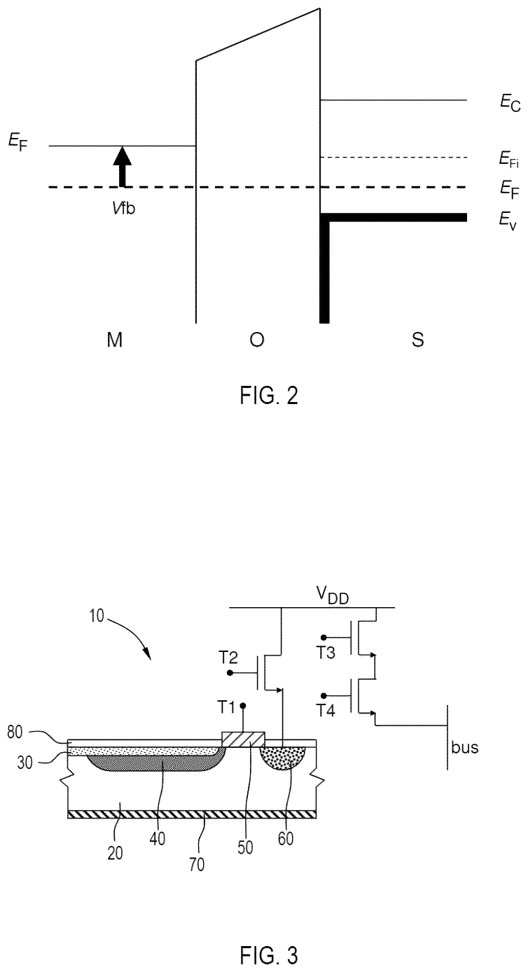

FIG. 2 illustrates an energy level diagram for a typical metal-oxide-semiconductor (MOS) system. The flat-band voltage (V_{fb}) is due to the work function between the metal (M) and semiconductor(S) and the charge in the substrate. In an ideal MOS system, the Fermi levels (E_{F}) in the metal (M) and semiconductor(S) align so that when zero voltage is applied, the energy bands are flat. In actual systems, the metal and semiconductor Fermi levels are not aligned so that when brought together there is a charge transfer will occur as the band on the surface of the semiconductor is bent. As voltage is applied, the energy level band becomes flat (as shown in FIG. 2). The voltage needed to flatten the energy band is referred to as the flat-band voltage (V_{fb}). The flat-band voltage is a component of the threshold voltage of the MOS system, so flat-band voltage increases resulting from increased current flowing through the substrate via the center tap results in an increase in the threshold voltage for the device.

The interface trapped charge (Dit) refers to the electrical charge trapped at the boundary of the different materials (e.g., at the metal-oxide boundary, or the oxide-semiconductor boundary). The interface trapped charge is measured as the formal charge per unit surface area (1/cm₂eV). The interface trapped charge can change the devices electrical properties by affecting the ability of charge carriers to trap and/or release electrons. The interface trapped charge can shift the threshold voltage of the device. An Increase in the interface trapped charge can Increase the leakage current of the device.

Fixed charges can have an impact on the dark current in a complementary metal-oxide-semiconductor (CIS) image sensor. CIS image sensors are commonly used in digital cameras and other imaging devices and include an array of pixels, where each pixel contains a photosensitive element called a photodiode. The photodiode converts light into an electrical signal, which is then processed to form an Image. The dark current refers to the electrical current that flows through the photodiode even when no light is present. This is mainly caused by thermal effects and can introduce noise into the image, reducing image quality. The fixed charges, also known as trapped charges, are electric charges that are trapped in the material of the image sensor and can affect the behavior of the photodiode and, consequently, the dark current. When fixed charges are present in the photodiode material, the electric field within the photodiode can be altered. The altered electric field can Increase the movement of charge carriers (electrons or holes) across the junction of the photodiode, which can cause an increase in the dark current. The presence of fixed charges can also affect the charge transfer efficiency of the photodiode. Charge transfer efficiency refers to how effectively the electrical charge generated by the photodiode is transferred to the readout circuitry. If the charge transfer efficiency is reduced due to the presence of fixed charges, higher dark current can result.

FIG. 3 illustrates a partial schematic diagram of a four transistor back-side illumination complementary metal-oxide-semiconductor (BSI CIS) image sensor 10. The image sensor 10 is illustrated for descriptive purposes but the skilled artisan will be familiar with this type of image sensor. The image sensor 10 includes a photosensitive region 30, a source region 40, a gate 50 and a drain region 60, formed on a substrate 20 typically made of polysilicon. A dielectric layer 80 covers the photosensitive region 30 in some embodiments. An anti-reflective coating, which is also a dielectric layer 70 is on the opposite side of the substrate 20 from the photosensitive region 30. Both the anti-reflective coating (dielectric layer 70) and the dielectric layer 80 can be affected by the accumulation of fixed charges.

Accordingly, one or more embodiments of the disclosure advantageously provide apparatus and methods to control the amount of charge flowing through the substrate during deposition. Some embodiments of the disclosure add a variable resistor in the electrostatic chuck (ESC) center tap cable. Some embodiments of the disclosure advantageously allow for Increasing the charge stored in an insulator (e.g., TaOx) film by reducing the resistance of the variable resistor so that more current flows through the ESC, and decreasing the charge stored in an insulator by increasing the resistance of the variable resistor. One or more embodiments of the disclosure advantageously allow for chamber matching using variable resistance to control and match the amount of electrons passing through the ESC surface of a process chamber to a reference chamber.

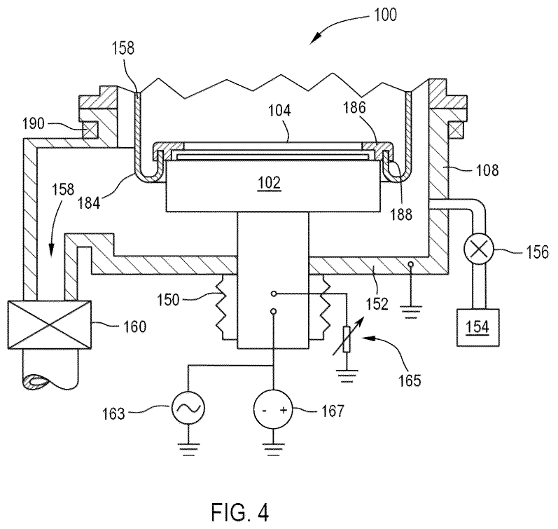

FIG. 4 shows a partial view of a physical vapor deposition process chamber 100 according to one or more embodiment of the disclosure. In this embodiment, a variable resistor 165 (also referred to as a resistance tuner) is coupled to the substrate support pedestal 102 and electrical ground. The variable resistor 165 of some embodiments is coupled between a DC power source 167 and the substrate support pedestal 102. While not illustrated, in some embodiments, both a capacitance tuner 164 and variable resistor 165 are connected to the substrate support pedestal 102. The capacitance tuner 164 of some embodiments is connected to electrical ground while the variable resistor 165 is connected to the DC power source 167, which can ground the variable resistor 165.

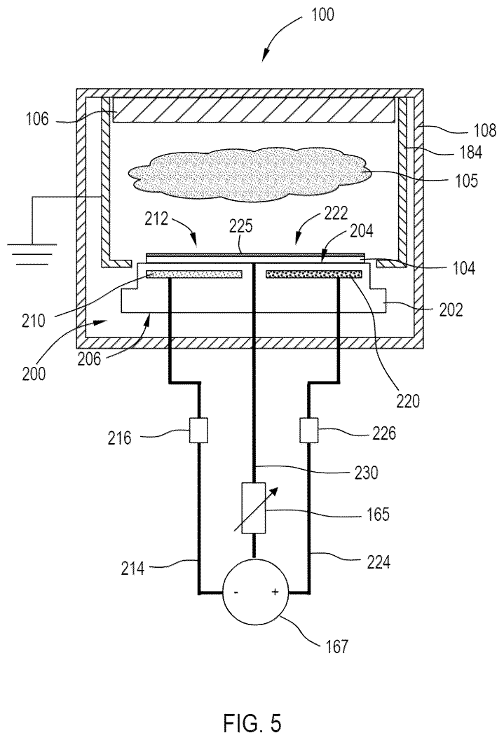

FIG. 5 Illustrates a schematic representation of a process chamber 100 including an electrostatic chuck 200 within the substrate support pedestal 102. The electrostatic chuck 200 comprises a support body 202 with a support surface 204 configured to support a substrate 104 during a deposition or etch process. The thickness of the support body 202 is measured from the support surface 204 to the bottom surface 206. The support body 202 of some embodiments is a generally disc shaped component with an outer peripheral edge. However, the support body 202 can be any suitable shape and size known to the skilled artisan.

The electrostatic chuck 200 can by any suitable configuration of known electrostatic chucks (ESCs) including, but not limited to, monopolar, bipolar and multi-polar ESCs. The electrostatic chuck 200 can be a coulombic ESC or a Johnsen-Rahbek type ESC, as will be understood by the skilled artisan. In the embodiments Illustrated and discussed herein, the electrostatic chuck 200 is a bipolar electrostatic chuck. The skilled artisan will understand how to apply the disclosed apparatus and methods with other types of electrostatic chucks.

The support body 202 includes a first electrode 210, a second electrode 220 and a center tap 230. Each of the first electrode 210 and second electrode 220 can be positioned at the support surface 204 or within the thickness of the support body 202. The center tap 230 is typically positioned in the approximate center of the support body 202 between the first electrode 210 and second electrode 220. The first electrode 210 is positioned in a first portion 212 of the support body 202. The second electrode is positioned in a second portion 222 of the support body 202 that is different than the first portion 212. In the bipolar ESC illustrated, the first portion 212 and second portion 222 are located in opposing halves of the support body 202 and the center tap 230 is between the first portion 212 and second portion 222. Other electrode arrangements within the support body 202 can be used with the center tap 230 located in a suitable position, as will be understood by the skilled artisan.

The electrostatic chuck 200 is powered by a suitable power source that is capable of chucking a substrate during processing. Suitable power supplies include, but are not limited to, DC power supplies and RF power supplies. The apparatus Illustrated in FIG. 4 has both RF bias power source 162 and a DC power source 167 connected to the support body 202. The internal wiring between the RF bias power source 162 and DC power source 167 and the electrostatic chuck electrodes are not shown; however, the skilled artisan will understand such configurations,

The first electrode 210 is connected to a power source (e.g., DC power source 167) configured to supply current and/or voltage to the first electrode 210 through a first transmission line 214. The second electrode 220 is connected to the power source to supply current and/or voltage to the second electrode 220 through a second transmission line 224. The center tap 230 is connected to the power source through a variable resistor 165. In some embodiments, the first electrode 210, second electrode 220 and center tap 230 are connected to and in electrical communication with a DC power source 167,

The variable resistor 165 can be any suitable resistor that is compatible with the process chamber hardware. Suitable resistors Include, but are not limited to, rheostats, digital resistors and potentiometers. In some embodiments, the variable resistor 165 is a digital resistor. In some embodiments, the digital resistor is controlled by the controller 110. In some embodiments, the controller 110 is configured to adjust the variable resistor 165 to maintain a current flow through the center tap 230 within a predetermined range.

The variable resistor 165 of some embodiments has a resistance up to and including 1 MΩ. In some embodiments, the variable resistor 165 has a resistance up to and including 900 kΩ, 800 kΩ, 700 kΩ, 600 kΩ, 500 kΩ, 400 kΩ, 300 kΩ, 200 kΩ, 100 kΩ, or 50 kΩ.

In some embodiments, one or more of the first transmission line 214 or the second transmission line 224 includes an RF filter 216, 226, respectively, in electrical communication between the DC power source 167 and the electrostatic chuck 200. The RF filters 216, 226 are configured to remove unwanted signals, frequencies and/or electrical noise that can interfere with the function of the electrostatic chuck 200. Suitable RF filters include, but are not limited to, band pass filters, band stop filters, low pass filters and high pass filters.

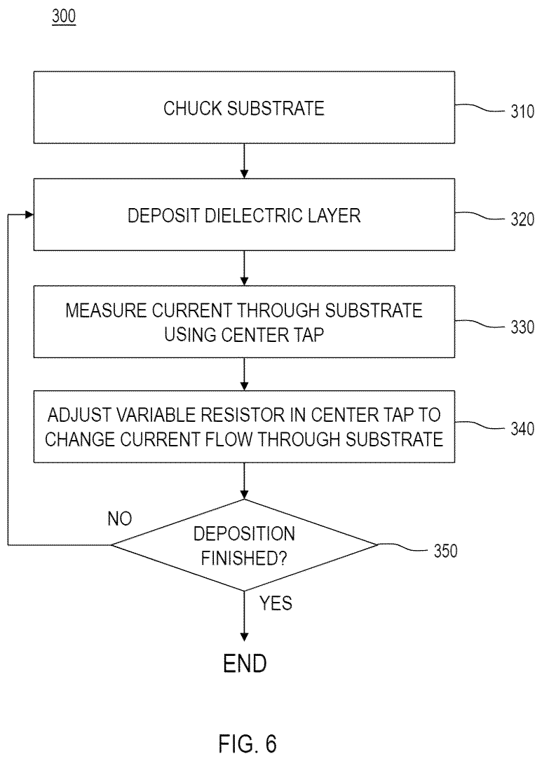

FIG. 6 shows a flowchart of a method 300 of controlling fixed charge in a dielectric layer 225. The method 300 of some embodiments is effective to maintain a uniform fixed charge throughout deposition of the dielectric layer 225. The method 300 is described with reference to FIGS. 5 and 6.

At operation 310, a substrate 104 is chucked to the support surface 204 of the electrostatic chuck 200 positioned within a process chamber 100. The electrostatic chuck 200 has a first electrode 210 in a first portion 212, a second electrode 220 in the second portion 222, and a center tap 230 positioned between the first electrode 210 and the second electrode 220. The center tap 230 is in electrical communication with electrical ground through a variable resistor 165. In the embodiment shown in FIG. 5, the center tap 230 connects to the DC power source 167 which can serve to ground the center tap 230.

At operation 320, a dielectric layer 225 is deposited by a plasma process onto the substrate 104. In some embodiments, the plasma process is a physical vapor deposition (PVD) process in which a plasma 105 causes atoms to be ejected from a target 106 toward the substrate 104. The skilled artisan will be familiar with the operation and maintenance of a physical vapor deposition chamber.

The dielectric layer 225 can be any suitable material known to the skilled artisan depending on, for example, the particular use of the layer. In some embodiments, the dielectric layer 225 is part of complementary metal-oxide-semiconductor image sensor, for example, like that shown in the schematic representation of FIG. 3. In some embodiments, the dielectric layer 225 comprises one or more of tantalum oxide (Taoₓ) or titanium oxide (TiOₓ). In some embodiments, the dielectric layer 225 comprises or consists essentially of tantalum oxide (Taoₓ). In some embodiments, the dielectric layer 225 comprises or consists essentially of titanium oxide (TIOₓ). As used in this manner, the term “consists essentially of” means that the stated component is greater than or equal to 95%, 98% or 99% of the stated material.

At operation 330 of method 300, the current passing through the substrate 104 during the deposition process is measured. The center tap 230 of the electrostatic chuck 200 is used to measure the current passing through the substrate. The measurement can be performed manually, using an in-line ammeter, or digitally through the power supply (e.g., DC power source 167).

At operation 340 of method 300, the variable resistor 165 of the center tap 230 is adjusted to control the amount of current flowing through the substrate 104. In some embodiments, adjusting the variable resistor 165 minimizes or controls the amount of fixed charge formation in the dielectric layer 225 by redirecting current flow from passing through the substrate to electrical ground to passing through a wall 108 of the processing chamber 100 in electrical communication with electrical ground 111. Operations 330 and 340 can be performed manually, or using controller 110.

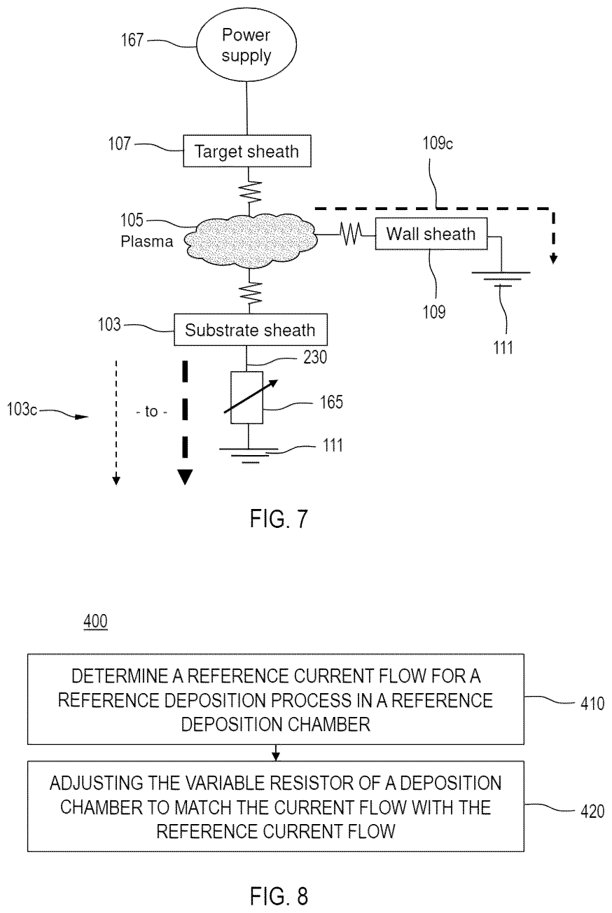

FIG. 7 illustrates a schematic representation of the electrical pathway of method 300. The power supply (e.g., DC power source 167) connects to the target 106 to generate the plasma 105. The plasma 105 causes deposition from the target 106 onto the substrate 104. The target sheath 107 is the interface between the target 106 and the plasma 105, and the substrate sheath 103 is the interface between the plasma 105 and the substrate 104. Some of the energy from the plasma 105 discharges through the chamber wall 108 of the process chamber 100. The wall sheath 109 is the interface between the plasma 105 and the chamber wall 108. Each of the target sheath 107, substrate sheath 103 and wall sheath 109 contribute resistance that results in the flow of current. The current 109c flowing through the wall sheath 109 is Illustrated as a fixed magnitude resulting from a fixed resistance (based on the thickness of the line), while the current 103c flowing through the substrate sheath 103 is variable based on the setting of the variable resistor 165. By adjusting the variable resistor 165, the relative current flow through the substrate sheath 103 and the wall sheath 109 can be adjusted, resulting in control of the fixed charge in the dielectric layer.

At decision point 350 of method 300, determination of whether the deposition process is complete is performed. If deposition is finished, the method 300 ends. If the deposition is not finished, operations 320, operation 330 and operation 340 are repeated, before reaching decision point 350 again. Operation 330 and operation 340 can be repeated many times during the deposition process in a dynamic manner. The measurement of the current through the substrate at operation 320 provides feedback for adjustment of the variable resistor 165 in operation 330,

FIG. 8 Illustrates a flowchart for a method 400 for chamber matching or tuning of a process chamber. At operation 410, the current flowing through a substrate on an electrostatic chuck is measured during deposition of a dielectric layer using the center tap of the electrostatic chuck for a plasma process in a reference processing chamber. This establishes a reference current flow for the reference deposition chamber. At operation 420, the variable resistor of the center tap of the electrostatic chuck of a process chamber (either the same process chamber or a different from the reference process chamber) is adjusted to match the reference current from the reference processing chamber established in operation 410.

Although the disclosure herein has been described with reference to particular embodiments, it is to be understood that these embodiments are merely Illustrative of the principles and applications of the present disclosure. It will be apparent to those skilled in the art that various modifications and variations can be made to the method and apparatus of the present disclosure without departing from the spirit and scope of the disclosure. Thus, it is Intended that the present disclosure includes modifications and variations that are within the scope of the appended claims and their equivalents.

1. A method of controlling fixed charge in a dielectric layer, the method comprising:
chucking a substrate to a support surface of an electrostatic chuck positioned within a processing chamber, the electrostatic chuck having a first electrode in a first portion, a second electrode in a second portion, and a center tap positioned between the first electrode and the second electrode and in electrical communication with electrical ground through a variable resistor;
depositing the dielectric layer on the substrate using a plasma in the processing chamber;
measuring current through the substrate during deposition using the center tap of the electrostatic chuck; and
adjusting the variable resistor of the center tap to control the current flowing through substrate.

2. The method of claim 1, wherein adjusting the variable resistor minimizes fixed charge formation in the dielectric layer by redirecting current flow from passing through the substrate to electrical ground to passing through a wall of the processing chamber in electrical communication with electrical ground.

3. The method of claim 1, wherein the dielectric layer comprises one or more of tantalum oxide or titanium oxide.

4. The method of claim 3, wherein the dielectric layer is part of complementary metal-oxide-semiconductor image sensor.

5. The method of claim 1, wherein measuring the current through the substrate and adjusting the variable resistor are performed by a controller.

6. The method of claim 1, wherein the variable resistor has a resistance up to 1 MΩ.

7. The method of claim 1, wherein the electrostatic chuck is a bipolar chuck with the first electrode and second electrode located in opposing halves of the electrostatic chuck.

8. The method of claim 7, wherein the electrostatic chuck is powered by a DC power source.

9. A method of tuning a processing chamber, the method comprising:
measuring current through a substrate on an electrostatic chuck during deposition of a dielectric layer using a plasma in the processing chamber, the current measured through a center tap of the electrostatic chuck; and
adjusting a variable resistor connected to the center tap to control the current flowing through the substrate to match a reference current from a reference processing chamber.

10. The method of claim 9, wherein adjusting the variable resistor controls a fixed charge formed in the dielectric layer by redirecting current flow from passing through the substrate to electrical ground to passing through a wall of the processing chamber in electrical communication with electrical ground.

11. The method of claim 9, wherein the dielectric layer comprises tantalum oxide.

12. The method of claim 9, wherein the variable resistor has a resistance up to 1 MΩ.

13. The method of claim 9, wherein the electrostatic chuck is a bipolar chuck with a first electrode and a second electrode located in opposing halves of the electrostatic chuck.

14. The method of claim 13, wherein the electrostatic chuck is powered by a DC power source.

15. An electrostatic chuck comprising:
a support body having a support surface;
a first electrode in a first portion of the support body, the first electrode connected to a power source through a first transmission line;
a second electrode in a second portion of the support body, different from the first portion, the second electrode connected to the power source through a second transmission line; and
a center tap between the first electrode and the second electrode, the center tap connected to the power source through a variable resistor.

16. The electrostatic chuck of claim 15, wherein the first electrode, second electrode and center tap are connected to a DC power source.

17. The electrostatic chuck of claim 16, wherein one or more of the first transmission line or the second transmission line includes an RF filter in electrical communication between the DC power source and the electrostatic chuck.

18. The electrostatic chuck of claim 15, further comprising a controller configured to adjust the variable resistor to maintain a current flow through the center tap within a predetermined range.

19. The electrostatic chuck of claim 15, wherein the variable resistor has a resistance up to 1 MΩ.

20. The electrostatic chuck of claim 15, wherein the electrostatic chuck is a bipolar chuck with the first portion and second portion located on opposing halves of the support body with the center tap between.
